(19) United States
(12) Patent Application Publication
(10) Pub. No.: US 2026/0313995 A1
(43) Pub. Date: Oct. 8, 2026

(54) ELECTRIC FIELD READOUT OF A SOLID-STATE SENSOR

(71) Applicant: RTX BBN Technologies, Inc., Cambridge, MA (US)

(72) Inventors: Erik Eisenach, Cambridge, MA (US); Martin Gustafsson, Cambridge, MA (US); Moe D. Soltani, Belmont, MA (US)

(21) Appl. No.: 19/640,071

(22) Filed: Apr. 6, 2026

Related U.S. Application Data
(60) Provisional application No. 63/783,672, filed on Apr. 4, 2025.

(51) Int. Cl. H10D 62/53; H10D 30/47; H10D 62/83; H10D 62/832; G01K 11/00; G01L 1/00; G01R 29/12; G01R 33/02

(52) U.S. Cl. CPC H10D 62/53; H10D 30/471; H10D 62/8303; H10D 62/8325; G01K 11/00; G01L 1/005; G01R 29/12; G01R 33/02

(57) ABSTRACT

A sensor may include a substrate with quantum defects, where ionization of the quantum defects by a stimulus from an ionization source forms free electrons in the substrate, and where an ionizability of the quantum defects by the stimulus is sensitive to a measurand. The sensor may further include a transistor circuit with one or more transistors to generate a detection signal indicative of the measurand based on electric field readout of the free electrons in the substrate when the stimulus is incident on the substrate.

### CROSS-REFERENCE TO RELATED APPLICATION

The present application claims the benefit under 35 U.S.C. § 119(e) of U.S. Provisional Application Serial Number 63/783,672, filed April 4, 2025 titled ELECTROSTATIC READOUT OF A SOLID-STATE SENSOR, naming Erik Eisenach, Martin Gustafsson, and Moe D. Soltani as inventors, which is incorporated herein by reference in the entirety.

### TECHNICAL FIELD

The present disclosure relates generally to quantum sensors and, more particularly, to quantum sensors incorporating readout using an FET device.

### BACKGROUND

Sensors that generate measurements based on solid-state spin states are a promising technology for many applications including, but not limited to, room-temperature measurements of electric fields, magnetic, strain, or temperature. However, existing technologies suffer from bulky readout components or low sensitivity. For example, existing techniques incorporating optical readout typically include bulk illumination and/or collection components that are designed for a specific application or measurement configuration (e.g., single-spin illumination and readout, ensemble illumination and readout, or the like). As a result, existing techniques suffer from a combination of high cost, low robustness in real-world applications, and/or inflexible operation. As another example, electrical readout of solid-state spins is a promising technique for low-SWAP (size, weight, and power) devices, but suffers from low sensitivity due to inefficiencies in collecting electrons from bulk material. Therefore there is a need for a scalable physical platform to address the above deficiencies.

### SUMMARY

In embodiments, the techniques described herein relate to a sensor including a substrate including quantum defects, where ionization of the quantum defects by a stimulus from an ionization source forms free electrons in the substrate, where an ionizability of the quantum defects by the stimulus is sensitive to a measurand; and a transistor circuit including one or more transistors to generate a detection signal indicative of the measurand based on electric field readout of the free electrons in the substrate when the stimulus is incident on the substrate.

In embodiments, the techniques described herein relate to a sensor, where the one or more transistors include a field-effect transistor (FET).

In embodiments, the techniques described herein relate to a sensor, where the one or more transistors include a high-electron mobility transistor (HEMT).

In embodiments, the techniques described herein relate to a sensor, where the transistor circuit includes one or more transistors in a discrete package coupled to the substrate.

In embodiments, the techniques described herein relate to a sensor, where a gate of at least one of the one or more transistors is coupled to the substrate through a biasing circuit.

In embodiments, the techniques described herein relate to a sensor, where at least one of the one or more transistors of the transistor circuit is fabricated on the substrate as integrated transistors.

In embodiments, the techniques described herein relate to a sensor, where a voltage is applied across the substrate to drive the electrons generated in response to the stimulus from ions in the substrate, where the ions gate a channel in the integrated transistors to provide the electric field readout.

In embodiments, the techniques described herein relate to a sensor, where the quantum defects have spin states sensitive to the measurand, where ionizability of the quantum defects is sensitive to the spin states, where the measurand selectively modifies spin states of portion of the quantum defects in proportion to a signal strength.

In embodiments, the techniques described herein relate to a sensor, where the substrate includes diamond, where the quantum defects include nitrogen vacancies.

In embodiments, the techniques described herein relate to a sensor, where the substrate includes silicon carbide, where the quantum defects include silicon vacancies.

In embodiments, the techniques described herein relate to a sensor, where the measurand includes at least one of a magnetic field, an electric field, temperature, or strain.

In embodiments, the techniques described herein relate to a sensor, where the defects include at least some engineered defects.

In embodiments, the techniques described herein relate to a sensor, where the defects include at least some naturally-occurring defects.

In embodiments, the techniques described herein relate to a sensor including a substrate including quantum defects; an ionization source configured to generate a stimulus, where ionization of the quantum defects by a stimulus from an ionization source forms free electrons in the substrate, where an ionizability of the quantum defects by the stimulus is sensitive to a measurand; a transistor circuit including one or more transistors to generate a detection signal indicative of the measurand based on electric field readout of the free electrons in the substrate when the stimulus is incident on the substrate; and a controller configured to generate one or more measurements of the measurand based on the detection signal.

In embodiments, the techniques described herein relate to a sensor, where the quantum defects have spin states sensitive to the measurand, where ionizability of the quantum defects is sensitive to the spin states, where the measurand modifies spin states of portion of the quantum defects in proportion to a signal strength.

In embodiments, the techniques described herein relate to a sensor, further including a conditioning source configured to generate a conditioning signal configured to align the spin states of the quantum defects, where the measurand flips the portion of the quantum defects in proportion to the signal strength.

In embodiments, the techniques described herein relate to a sensor, where the transistor circuit includes one or more transistors in a discrete package coupled to the substrate, where a gate of at least one of the one or more transistors is coupled to the substrate through a biasing circuit.

In embodiments, the techniques described herein relate to a sensor, where at least one of the one or more transistors of the transistor circuit is fabricated on the substrate as integrated transistors, where a voltage is applied across the substrate to drive the electrons generated in response to the stimulus from ions in the substrate, where the ions gate a channel in the integrated transistors to provide the electric field readout.

In embodiments, the techniques described herein relate to a sensor, where the one or more transistors include a FET.

In embodiments, the techniques described herein relate to a sensor, where the measurand includes at least one of a magnetic field, an electric field, temperature, or strain.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1 illustrates a block diagram of a sensor, in accordance with one or more embodiments of the present disclosure.

FIG. 2A illustrates a simplified schematic diagram of a transistor circuitry including a field-effect transistor (FET) having contacts fabricated on surfaces of the substrate, in accordance with one or more embodiments of the present disclosure.

FIG. 2B illustrates conceptually the operation of the sensor for sensing a magnetic field, in accordance with one or more embodiments of the present disclosure.

FIG. 3 is a schematic circuit diagram of a sensor including a substrate and transistor circuitry as discrete packages, in accordance with one or more embodiments of the present disclosure.

### DETAILED DESCRIPTION

Before explaining one or more embodiments of the disclosure in detail, it is to be understood the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure the embodiments disclosed herein may be practiced without some of these specific details. In other instances, well-known features may not be described in detail to avoid unnecessarily complicating the instant disclosure.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of “a” or “an” may be employed to describe elements and components of embodiments disclosed herein. This is done merely for convenience and “a” and “an” are intended to include “one,” “one or more,” or “at least one,” and the singular also includes the plural unless it is obvious that it is meant otherwise.

Finally, as used herein any reference to “one embodiment” or “some embodiments” means that a particular element, feature, structure, or characteristic described in connection with the embodiment is included in at least one embodiment disclosed herein. The appearances of the phrase “in some embodiments” in various places in the specification are not necessarily all referring to the same embodiment, and embodiments may include one or more of the features expressly described or inherently present herein, or any combination of or sub-combination of two or more such features, along with any other features which may not necessarily be expressly described or inherently present in the instant disclosure.

Embodiments of the present disclosure are directed to systems and methods providing electric field readout of a sensor having quantum defects that are sensitive to a measurand (e.g., a measurable property of interest) such as, but not limited to, temperature, strain, electric field, or magnetic fields.

In embodiments, an ionizability of the quantum defects is sensitive to the measurand. In this configuration, when the quantum defects are exposed to a stimulus from an ionization source (e.g., incident light from a light source, or the like), free electrons are generated in the substrate, where a population of free electrons is proportional to a strength of the measurand either directly or inversely.

In embodiments, the sensor includes a transistor circuit having one or more field-effect transistors (FET) configured to provide electric field readout of the free electrons in the substrate while the free electrons remain in the substrate. This transistor circuit may be provided as a discrete package separate from the substrate or at least partially fabricated on the substrate to provide an integrated package.

As used herein, the term electric field readout may refer to any technique for measuring free electrons in a substrate (or ionization of quantum defects more generally) without requiring extraction of electrons from the substrate during a measurement. It is contemplated herein that electric field readout may overcome deficiencies in existing techniques and provide sensitive and scalable measurements. For example, traditional electrical readout techniques suffer from losses associated with extraction of free electrons from a bulk substrate and thus corresponding lower signal to noise ratio (SNR) performance. In contrast, electric field readout does not require electrons to leave the substrate and is not subject to these losses. Further electric field readout may be implemented with compact form factors to provide high size, weight, and power (SWAP) performance.

In some embodiments, the quantum defects have spin states that are sensitive to the measurand. In this case, the sensor may be solid-state spin sensor. It is recognized herein that spin-based detectors are a promising platform for a variety of measurements including, but not limited to, temperature, strain, electric field, or magnetic fields. For instance, spin states and transitions of defects such as NV centers in diamond are sensitive to such measurable properties. However, existing technologies for manipulating and reading out spin states either rely on collection of light or electrons outside the substrate which hosts the defects, which both provide low SWAP performance and/or low SNR.

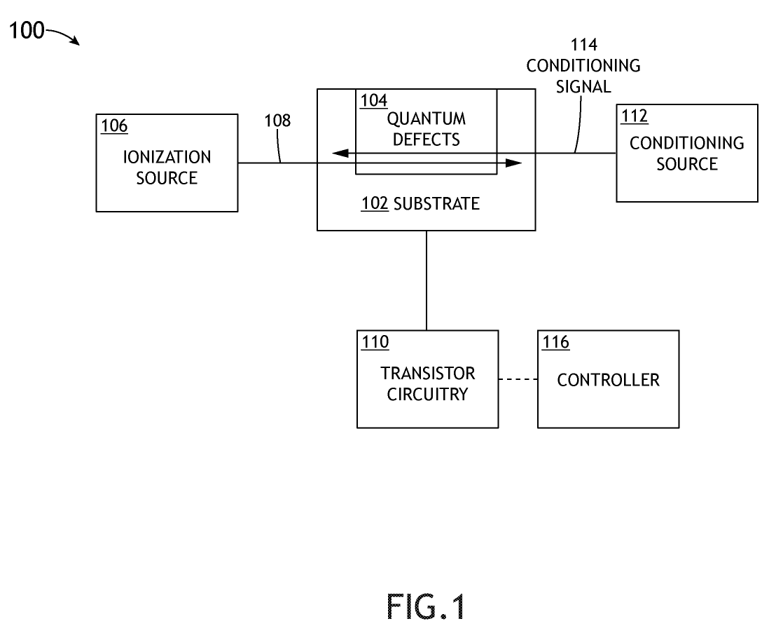

Referring now to FIGS. 1-3, systems and methods providing electric field readout of quantum defects, in accordance with one or more embodiments of the present disclosure.

FIG. 1 illustrates a block diagram of a sensor 100, in accordance with one or more embodiments of the present disclosure.

In some embodiments, a sensor 100 includes a substrate 102 with quantum defects 104 that are sensitive to a measurand (e.g., a measurable property of interest). In particular, an ionizability of the quantum defects 104 may be sensitive to the measurand. In this configuration, a strength of the measurand may impact a proportion of the quantum defects 104 that are ionizable. In some cases, the measurand increases an ionizability of the quantum defects 104. In some cases, the measurand decreases an ionizability of the quantum defects 104.

The measurand may include any measurable property of interest that may influence the ionizability of the quantum defects such as, but not limited to, temperature, strain, electric field, or magnetic field.

The substrate 102 may include any material that may have either naturally-occurring quantum defects 104 or engineered quantum defects 104 that are sensitive to a measurand of interest (e.g., a measurable property of interest). For example, the quantum defects 104 may have an ionizability that is sensitive to the measurand.

Further, the quantum defects 104 may be of any type such as, but not limited to, color centers, vacancy defects, or the like. For example, the substrate 102 may include diamond, where the quantum defects 104 are nitrogen vacancy (NV) defects. As another example, the substrate 102 may include silicon carbide (SiC), where the quantum defects 104 are silicon vacancy (SV) defects. In each of these examples, the quantum defects 104 may have spin states that may be aligned by a magnetic field, where the spin-aligned spin states (e.g., spin-up states) may be selectively ionized or de-ionized by an ionization source. Further, these substrates have excellent thermal conductivity, which may facilitate low-noise measurements. However, these examples are merely illustrative and do not limit the spirit or scope of the present disclosure. For example, the quantum defects 104 are not limited to spin-state defect types.

The quantum defects 104 may further include any combination of naturally-occurring or engineered defects. For example, at least some of the quantum defects 104 may be associated with dopants and/or structural defects. As an illustration in the case of NV centers in diamond, at least some of the NV centers may be formed from a delta-doped layer in the diamond.

In some embodiments, the sensor 100 includes an ionization source 106 to generate a stimulus 108 to selectively ionize quantum defects 104 (e.g., quantum defects 104 in an ionizable state) to generate free electrons in the substrate 102, where a proportion of the quantum defects 104 in the ionizable state, and thus a population of free electrons in the substrate 102, depends on a strength of the measurand.

The ionization source 106 may provide any stimulus 108 suitable for ionizing quantum defects 104. For example, the ionization source 106 may include an electromagnetic source (e.g., a light source) suitable for providing a stimulus 108 including light or any electromagnetic wave of any wavelength. For example, the ionization source may include, but is not limited to, a laser source, a light-emitting diode (LED) source. As an illustration, NV quantum defects 104 in a diamond substrate 102 may be photoionized by light having a wavelength around 532 nm. As another example, SV quantum defects 104 in a SiC substrate may be photoionized by light having a wavelength in a range of around 750 nm to 800 nm. Further, the stimulus 108 may be continuous-wave or pulsed with any pulse duration or repetition rate suitable for the application of interest. In some embodiments, the ionization source 106 has sufficient power to ionize all (or at least a majority) of quantum defects 104 in the substrate 102 that are in an ionizable state.

In some embodiments, the sensor 100 includes transistor circuitry 110 including one or more transistors configured to provide electric field readout of the free electrons in the substrate 102. It is contemplated herein that electric field readout (e.g., contactless electrometry) may provide a detector signal that is indicative of a population of free electrons in the substrate 102 and thus indicative of a strength of the measurand without requiring extraction of the free electrons from the substrate 102. As a result, electric field readout may avoid losses associated with the extraction of free electrons from the substrate 102 (e.g., losses due to poor ohmic contacts, or the like) and provide highly sensitive measurements.

The transistor circuitry 110 may include any number or type of transistors suitable for electric field readout. For example, the one or more transistors may include, but are not limited to one or more field-effect transistors (FETs). In some cases, the one or more transistors include high-electron mobility transistors (HEMTs).

The transistor circuitry 110 may implement electric field readout of free electrons in the substrate 102 using any suitable technique. In some embodiments, the transistor circuitry may include one or more transistors with contacts integrated with or connected to the substrate 102. For example, a current and/or voltage between contacts of the transistor circuitry 110 may be sensitive to the presence of the photoionized quantum defects 104 without requiring that free electrons from the substrate 102 enter the transistor circuit. In this way, the transistor circuitry 110 may include any component or combination of components suitable for measuring current and/or voltage including, but not limited to, current sensors, voltage sensors, or amplifiers.

In some embodiments, an electric field is applied across the substrate 102 (e.g., through application of a voltage or any other technique) to separate free electrons and ions associated with photoionized quantum defects 104, which may assist in the electric field measurement.

The transistor circuitry 110 may be provided as a discrete package separate from the substrate 102 or at least partially integrated with the substrate 102. For example, the transistor circuitry 110 may be fabricated using any suitable technique or platform and coupled with the substrate 102 to form the sensor 100. Such an approach may enable separate design and optimization of the transistor circuitry 110. As another example, at least portion of one or more transistors may be fabricated on surfaces of the substrate 102 to form an integrated solution. Such a configuration may promote tight integration and excellent SWAP performance.

In some embodiments, the sensor 100 includes one or more conditioning sources 112 to generate a conditioning signal 114 that conditions the quantum defects 104 and/or free electrons in the substrate 102 for a measurement.

For example, spin sensitivity of spin-state quantum defects 104 (e.g., color centers, or the like) to a measurand may be improved through cycles of optical activation at lower energies than what is required for ionization followed by relaxation. Accordingly, a conditioning source 112 may include an additional light source to generate a conditioning signal 114 (e.g., light) with parameters (e.g., wavelength, power, pulse duration, repetition rate, or the like) suitable for preparing spin and/or charge states of the quantum defects 104. In some embodiments, the conditioning source 112 is a light source configured to generate green pump light as a conditioning signal 114 (e.g., at a wavelength around 530 nm), which may be suitable for preparing spin and/or charge states of quantum defects 104 in diamond or silicon carbide. In some embodiments, the conditioning source 112 is a field source configured to generate electric or magnetic fields as conditioning signals 114.

In some embodiments, a conditioning source 112 may include includes a field source suitable for providing an electric or magnetic field. For example, readout of quantum defects 104 may be implemented using conditioning signals such as, but not limited to, a magnetic field and/or an electric field (e.g., an RF electric field).

In a general sense, one or more conditioning sources 112 may be used to implement any conditioning technique for quantum defect readout, including those known in the art.

In some embodiments, any combination of the transistor circuitry 110, the conditioning source 112, and/or the ionization source 106 may be integrated together or performed by a common component. In this way, the nomenclature of transistor circuitry 110, the conditioning source 112, and/or the ionization source 106 is merely for illustrative purposes and is not limiting on the scope of the present disclosure.

Taken together, the ionization source 106, the conditioning source 112 if present, and/or the transistor circuitry 110 may produce photoionization of the quantum defects 104 that is sensitive to the measurand and may thus form a basis for a measurement. As an illustration in the case of spin-state quantum defects 104, the presence of the measurand may modify the spin states of a portion of the quantum defects 104 in proportion to the strength of the measurand. For example, the measurand may flip spin states from a non-ionizable state (or a weakly ionizable state) to an ionizable state or alternatively flip spin states from an ionizable state to a non-ionizable state (or a weakly ionizable state). In any case, the strength of the measurand will impact the population of free electrons and thus form the basis of a measurement.

In some embodiments, the sensor 100 includes a controller 116 to generate one or more measurements of the property of interest based on signals from the transistor circuitry 110. The controller 116 may include one or more processors suitable for executing program instructions stored on a memory device such as, but not limited to, a non-transitory memory device. For instance, the controller 116 may include a digital signal processor (DSP), a field-programmable gate array (FPGA) device, an application-specific integrated circuit (ASIC), a central processing unit (CPU), or a graphical processing unit (GPU). The controller 116 may further provide additional functions such as, but not limited to, calibrating the measurements based on calibration data.

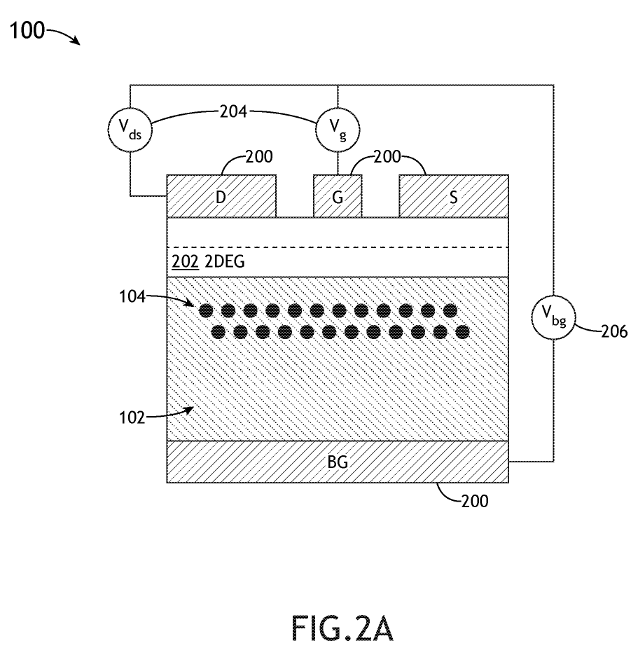

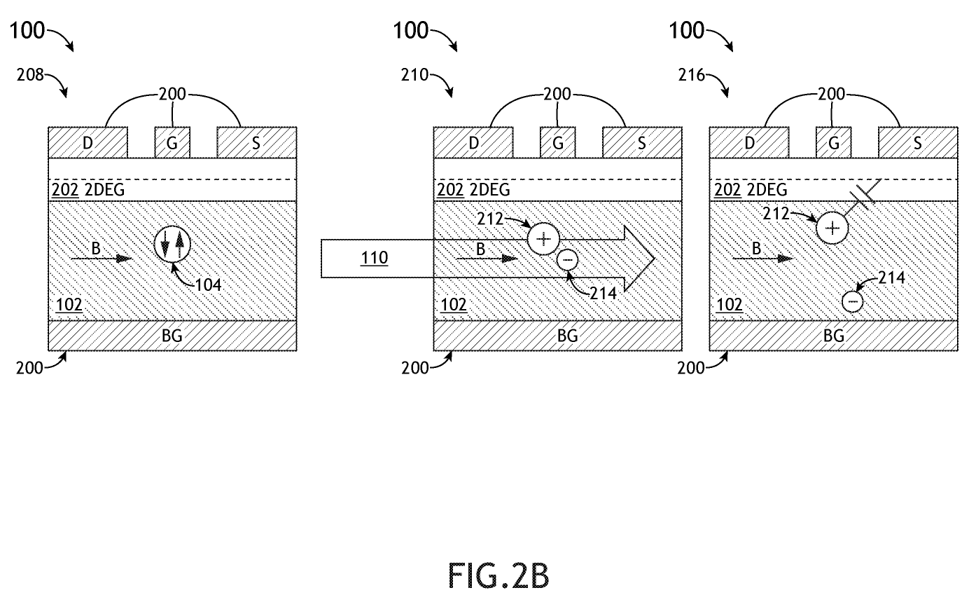

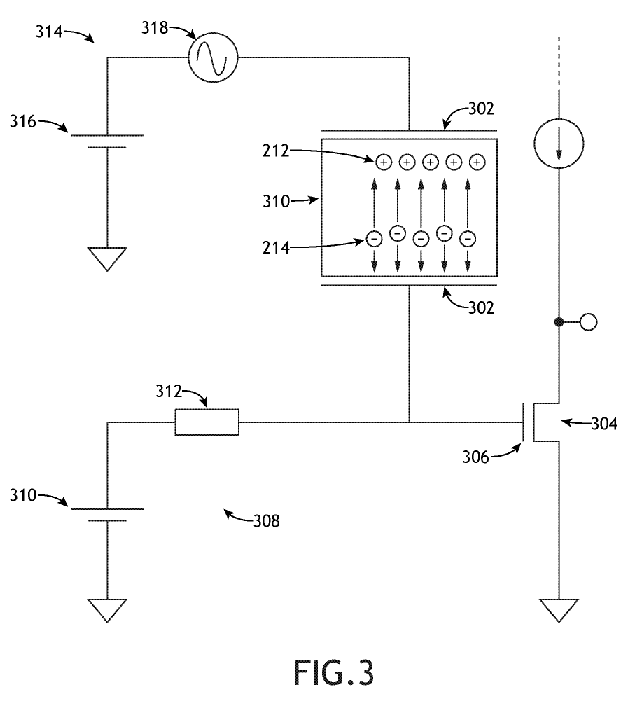

Referring now to FIGS. 2A-3, various nonlimiting configurations of the sensor 100 are described in greater detail, in accordance with one or more embodiments of the present disclosure.

FIGS. 2A-2B depict a non-limiting example of an integrated solution in which contacts form gates of a FET.

In some embodiments, the transistor circuitry 110 includes a FET device. In this configuration, the quantum defects 104 may be located in the substrate 102 and sufficiently close to a 2DEG region 202 such that current through the 2DEG region may be affected when at least some of the quantum defects 104 are photoionized by the stimulus 108. For example, quantum defects 104 may be distributed throughout the substrate 102 or may be isolated to selected locations (e.g., a shallow level or a deep level) in the substrate 102.

FIG. 2A illustrates a simplified schematic diagram of a transistor circuitry 110 including a FET having contacts 200 fabricated on surfaces of the substrate 102, in accordance with one or more embodiments of the present disclosure. In some embodiments, the transistor circuitry 110 includes a HEMT. The components of FIG. 2A are not drawn to scale.

In FIG. 2A, the sensor 100 is depicted with a 2DEG region 202 on the substrate 102. The 2DEG region 202 may be formed from any suitable materials including, but not limited to, group III-IV elements. For example, the 2DEG region may be formed from GaN, GaAs, or the like. Quantum defects 104 (e.g., NVs in diamond, SVs in SiC, or any other suitable quantum defects 104 in any other suitable substrate 102) are shown in the substrate 102 near the 2DEG region 202.

FIG. 2A depicts various contacts 200, which may be suitable for operation of the FET and/or charge separation of photoionized defects. For example, FIG. 2A depicts a drain contact (D), a source contact (S), a gate contact (G), which may be used for operation of the FET to generate current flow through the 2DEG region 202. As an illustration, FIG. 2A depicts sources 204 (shown as Vds and Vg) to control operation of the FET. FIG. 2A further depicts a back gate contact (BG) on a back surface of the substrate 102, which may be used to assist with charge separation. For example, FIG. 2A depicts a voltage source 206 (Vbg) to apply a voltage across the substrate to separate electrons and ions after photoionization. It is noted that although FIG. 2A depicts the voltage source 206 connected between the source contact 200 (S) and the back gate contact 200 (BG), this is merely illustrative and not limiting on the scope of the present disclosure. A voltage may be applied between the back gate contact 200 (B) and any suitable contact on an opposing side of the substrate 102 including, but not limited to, the gate contact (G), the drain contact (D), or another contact (not shown) that not otherwise associated with the operation of the FET.

FIG. 2B illustrates conceptually the operation of the sensor 100 for sensing a magnetic field, in accordance with one or more embodiments of the present disclosure. In FIG. 2B, connections between the various contacts 200 are not shown for clarity.

Panel 208 illustrates the alignment of spin states of single defect 104 in response to a magnetic field (B), which corresponds to the measurand (e.g., the property measured by the sensor 100). Panel 210 illustrates the selective photoionization of the defect 104, which generates a positive ion 212 and an electron 214. Panel 216 illustrates charge separation and electrostatic coupling of the ion 212 with the 2DEG region 202 which is illustrated with a capacitance symbol. As depicted in panel 216, the electron freed during photoionization in panel 210 may drift away (e.g., towards the back gate) to induce charge separation in the substrate 102, which may impact current flow in the 2DEG region 202 (e.g., between the source contact 200 (S) and the drain contact 200 (D)). In particular, applying of an electric field across the substrate 102 may facilitate charge separation and mitigate recombination. The electric field may be generated by any suitable technique including, but not limited to, driving a voltage between the back gate contact 200 (BG) and one or more contacts 200 on a top surface of the substrate 102.

Further, it is contemplated herein that the 2DEG region 202 may act as an integrated amplifier, which may operate to increase a strength of a signal that is sensitive to the charge separation and thus sensitive to the presence of the magnetic field (or other measurable property). This amplification may facilitate both relatively high sensitivity and signal to noise ratio (SNR).

Referring generally to FIGS. 2A-2B, it is to be understood that FIGS. 2A-2B are merely illustrative and should not be interpreted as limiting the scope of the present disclosure. For example, the transistor circuitry 110 is not limited to a FET or HEMT and may include any transistor architecture that may provide electric field detection of photo-ionized defects. In some embodiments, the transistor circuitry 110 is a single-electron transistor.

FIG. 3 is a schematic circuit diagram of a sensor 100 including a substrate 102 and transistor circuitry 110 as discrete packages, in accordance with one or more embodiments of the present disclosure. In FIG. 3, the substrate 102 includes one or more metalized surfaces 302 to facilitate electrical connections with the transistor circuitry 110.

In some embodiments, as shown in FIG. 3, the transistor circuitry 110 includes a FET 304 with a gate 306 connected to the crystal to provide electric field sensing of free electrons within the substrate 102. The transistor circuitry 110 may include bias circuitry 308 to bias the gate of the FET 304 (e.g. with a DC bias voltage). For example, FIG. 3 depicts the bias circuitry 308 as a voltage source 310 and a resistor 312. However, this is merely an illustration and not limiting on the scope of the present disclosure. The bias circuitry 308 may include any components suitable for biasing any transistors in the transistor circuit 110 to desired operational levels.

In some embodiments, the transistor circuitry 110 includes drive circuitry 314 to induce controlled oscillations in the free electrons 214 generated in response to the stimulus 108 from the ionization source 106. For example, the drive circuitry 314 may induce oscillations of the free electrons to facilitate sensitive electric field measurements away from direct-current (DC) or low frequency noise sources. As an illustration, FIG. 3 depicts DC voltage 316 and alternating-current (AC) voltage 318 contributions. However, this is merely illustrative and not limiting on the scope of the present disclosure. The drive circuitry 314 may include any combination of components suitable for driving or manipulating an electric field measurement.

More generally, it is contemplated herein that the sensor 100 may be operated at any frequency range such as, but not limited to, DC operation to MHz frequencies or higher. For example, the sensor 100 may at higher frequencies than existing quantum sensors.

Referring now generally to FIGS. 1-3, it is contemplated herein that the substrate 102 may have thickness suitable for facilitating measurements of selectively ionized quantum defects 104. For example, in the case where the transistor circuitry 110 includes a FET integrated with the substrate 102, the thickness should be large enough that the mobile electrons (that result from ionization) do not induce substantial charge on the FET channel. That is, it should be thick compared to the distance between the FET channel and the quantum defects 104, or comparable to this distance. In some cases, the quantum defects 104 are separated from the FET by a distance of approximately 1 micrometer, so thicknesses below 10 micrometers may be feasible. Once the thickness of the substrate 102 is many times the defect-heat distance, there may be little or no benefit to increasing the thickness. Further, it may be desirable to limit the distance charges associated with ionization travel. In some embodiments, the substrate 102 has a thickness of 500 micrometers or lower. It is noted that 500 micrometers is a standard substrate thickness that is sturdy enough to process without being attached to a carrier substrate while also being suitable for operation in the sensor 100. In some embodiments, the substrate 102 has a thickness in a range of 1 micrometer to 500 micrometers. In some embodiments, the substrate 102 has a thickness in a range of 10 micrometers to 100 micrometers. In some embodiments, the substrate 102 has a thickness in a range of 10 micrometers to 500 micrometers.

Although the disclosure has been described with reference to the embodiments illustrated in the attached drawing figures, equivalents may be employed and substitutions made herein without departing from the scope of the claims. Components illustrated and described herein are merely examples of a system/device and components that may be used to implement embodiments of the disclosure and may be replaced with other devices and components without departing from the scope of the claims. Furthermore, any dimensions, degrees, and/or numerical ranges provided herein are to be understood as non-limiting examples unless otherwise specified in the claims.

What is claimed:

1. A sensor comprising:
a substrate including quantum defects, wherein ionization of the quantum defects by a stimulus from an ionization source forms free electrons in the substrate, wherein an ionizability of the quantum defects by the stimulus is sensitive to a measurand; and
a transistor circuit including one or more transistors to generate a detection signal indicative of the measurand based on electric field readout of the free electrons in the substrate when the stimulus is incident on the substrate.

2. The sensor of claim 1, wherein the one or more transistors comprise:
a field-effect transistor (FET).

3. The sensor of claim 2, wherein the one or more transistors comprise:
a high-electron mobility transistor (HEMT).

4. The sensor of claim 1, wherein the transistor circuit includes one or more transistors in a discrete package coupled to the substrate.

5. The sensor of claim 4, wherein a gate of at least one of the one or more transistors is coupled to the substrate through a biasing circuit.

6. The sensor of claim 1, wherein at least one of the one or more transistors of the transistor circuit is fabricated on the substrate as integrated transistors.

7. The sensor of claim 6, wherein a voltage is applied across the substrate to drive the electrons generated in response to the stimulus from ions in the substrate, wherein the ions gate a channel in the integrated transistors to provide the electric field readout.

8. The sensor of claim 1, wherein the quantum defects have spin states sensitive to the measurand, wherein ionizability of the quantum defects is sensitive to the spin states, wherein the measurand selectively modifies spin states of portion of the quantum defects in proportion to a signal strength.

9. The sensor of claim 8, wherein the substrate comprises diamond, wherein the quantum defects comprise nitrogen vacancies.

10. The sensor of claim 8, wherein the substrate comprises silicon carbide, wherein the quantum defects comprise silicon vacancies.

11. The sensor of claim 1, wherein the measurand comprises:
at least one of a magnetic field, an electric field, temperature, or strain.

12. The sensor of claim 1, wherein the defects include at least some engineered defects.

13. The sensor of claim 1, wherein the defects include at least some naturally-occurring defects.

14. A sensor comprising:
a substrate including quantum defects;
an ionization source configured to generate a stimulus, wherein ionization of the quantum defects by a stimulus from an ionization source forms free electrons in the substrate, wherein an ionizability of the quantum defects by the stimulus is sensitive to a measurand;
a transistor circuit including one or more transistors to generate a detection signal indicative of the measurand based on electric field readout of the free electrons in the substrate when the stimulus is incident on the substrate; and
a controller configured to generate one or more measurements of the measurand based on the detection signal.

15. The sensor of claim 14, wherein the quantum defects have spin states sensitive to the measurand, wherein ionizability of the quantum defects is sensitive to the spin states, wherein the measurand modifies spin states of portion of the quantum defects in proportion to a signal strength.

16. The sensor of claim 15, further comprising:
a conditioning source configured to generate a conditioning signal configured to align the spin states of the quantum defects, wherein the measurand flips the portion of the quantum defects in proportion to the signal strength.

17. The sensor of claim 14, wherein the transistor circuit includes one or more transistors in a discrete package coupled to the substrate, wherein a gate of at least one of the one or more transistors is coupled to the substrate through a biasing circuit.

18. The sensor of claim 14, wherein at least one of the one or more transistors of the transistor circuit is fabricated on the substrate as integrated transistors, wherein a voltage is applied across the substrate to drive the electrons generated in response to the stimulus from ions in the substrate, wherein the ions gate a channel in the integrated transistors to provide the electric field readout.

19. The sensor of claim 14, wherein the one or more transistors comprise:
a field-effect transistor (FET).

20. The sensor of claim 14, wherein the measurand comprises:
at least one of a magnetic field, an electric field, temperature, or strain.
